(19) United States
(12) Patent Application Publication
(10) Pub. No.: US 2007/0288831 A1
(43) Pub. Date: Dec. 13, 2007

(54) TRANSCODEC DEVICE

(75) Inventor: Mitsunori HOUKI, Kyoto (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/752,665

(22) Filed: May 23, 2007

(30) Foreign Application Priority Data
May 25, 2006 (JP) 2006-145955

(51) Int. Cl. H03M 13/00

(52) U.S. Cl. 714/776

(57) ABSTRACT

A transcodec device is provided which suppresses deterioration in image quality after coding, even when a failure and the like has occurred during the decoding process.

A transcodec device which converts an inputted video bit stream which is in a first format into a video bit stream in a second format, which includes a decoding unit which decodes the video bit stream in the first format; a determination unit which determines, when a failure is detected in the video bit stream of the first format during the decoding process by the decoding unit, an error recovery method for a portion of data in which the failure is detected, in such a way that a coding process of the video bit stream is performed by correcting the portion of the data in which the failure is detected using a portion of data in which the failure in the video bit stream in the first format is detected; and a coding unit which codes the portion of data in which the failure has been detected, according to the error recovery method determined by the determination unit.

### BACKGROUND OF THE INVENTION

(1) Field of the Invention

The present invention relates to a transcodec device which decodes a coded bit stream and codes the decoded data.

(2) Description of the Related Art

FIG. 1 is a diagram which shows the structure of a conventional transcodec device.

The conventional transcodec device consists of a decoding unit 1000 which decodes an inputted bit stream, and a coding unit 1001 which codes decoded data outputted from the decoding unit 1000.

The decoding unit 1000 loads an inputted bit stream from a signal line 1010 and performs a decoding process on the inputted bit stream. The decoding unit 1000 outputs decoded data via a signal line 1020 to the coding unit 1001 and further, detects the coding parameter included in the inputted bit stream and outputs decoded data to the coding unit 1001 via a signal line 1021. The coding unit 1001 loads decoded data via the signal line 1020 and loads a coding parameter through the signal line 1021. The coding unit 1001 codes decoded data loaded via the signal line 1020, using the coding parameter received from the decoding unit 1000 and outputs the coded data through a signal line 1030.

In this way, when decoded data is coded again in the conventional configuration, the decoding unit 1000 sends only decoded data and a coding parameter to the coding apparatus 1001 (see for example, Japanese Laid-Open Patent No. 2002-77925 Publication).

However, in the conventional configuration, when there is an error in the inputted bit stream, coding processing is performed without the coding unit 1001 recognizing that the inputted bit stream includes an error, since the error is not communicated from the decoding unit 1000 to the coding unit 1001. As a result, there is the problem that image quality drops after coding.

Further, in the conventional configuration, when decoding is interrupted in process, coding is performed without the decoding unit 1001 recognizing that the decoding has been interrupted, since information which indicates that decoding has been interrupted is not communicated from the decoding unit 1000 to the coding unit 1001. As a result, there is the problem that image quality drops after coding.

### SUMMARY OF THE INVENTION

The present invention is realized in order to solve the problem above and takes as an object providing a transcodec device for suppressing deterioration in image quality after re-coding, even in the case where a failure and the like occurs during the decoding process.

In order to accomplish the objectives above, the transcodec device converts an inputted video bit stream which is in a first format into a video bit stream in a second format, the transcodec device including: a decoding unit which decodes the video bit stream in the first format; a determination unit which determines, when a failure is detected in the video bit stream of the first format during the decoding process by the decoding unit, an error recovery method for a portion of data in which the failure is detected, in such a way that a coding process of the video bit stream is performed by correcting the portion of the data in which the failure is detected using a portion of data in which the failure in the video bit stream in the first format is detected; and a coding unit which codes the portion of data in which the failure has been detected, according to the error recovery method determined by the determination unit.

For example, the failure is a bit stream error which is included in the bit stream or an interruption during the decoding process.

For example, the determination unit determines the error recovery method in such a way that the coding process is performed by switching a unit of data to be coded for a unit of data which does not include the failure, when a unit of data to be coded includes the failure.

For example, the data unit is a picture basis, a slice basis, or a macroblock basis.

For example, the determination unit determines the error recovery method in such a way that the coding process is performed by switching a unit of data to be coded for a unit of data which does not include the failure and reduce a motion vector of the switched data unit to 0, when the data unit to be coded includes the failure.

For example, the data unit is a picture basis, a slice basis or a macroblock basis.

For example, the determination unit determines the error recovery method based on the number of macroblocks which are affected by the bit stream error.

For example, the determination unit (A) determines the error recovery method in such a way that the coding process is performed after error concealment is performed on a frame or a picture which includes the failure when the number of macroblocks which are affected by the bit stream error in the frame or the picture which includes the failure is equal to or greater than a first threshold value and equal to or less than a second threshold value which is greater than the first threshold value; and (B) determines the error recovery method in such a way that the coding process is performed by switching the frame or the picture which includes the failure to the frame or picture which does not include the failure when the number of the macroblocks which are affected by the bit stream error in the frame or the picture which includes the failure exceeds the second threshold value.

For example, the decoding unit performs error concealment on a unit of data which includes the failure, and the determination unit determines the error recovery method based on a difference between a motion vector included in a unit of data which does not include the failure and a motion vector used in error concealment performed by the decoding unit.

For example, the determination unit determines the error recovery method in such a way that the coding process is performed after error concealment is performed on the data unit which includes the failure.

For example, the determination unit determines the error recovery method in such a way that the coding process is performed after the error concealment process is performed, using the motion vector of the data unit which does not include the failure decoded by the decoding unit, only when the difference is outside of a specified range.

For example, the data unit is a picture basis, a slice basis or a macroblock basis.

For example, the decoding unit performs error concealment on a unit of data which includes the failure; and the determination unit determines the error recovery method based on a difference between a motion vector used in error concealment performed by the decoding unit and a motion vector obtained in coding finished by the coding unit.

For example, the determination unit determines the error recovery method in such a way that the coding process is performed after error concealment is performed on the data unit which includes the failure.

For example, the determination unit determines the error recovery method in such a way that the coding method is performed after error concealment is performed using the motion vector obtained in the coding, only when the difference is outside of a specified range.

For example, the data unit is a picture basis, a slice basis or a macroblock basis.

For example, the determination unit determines one of: (A) a method for performing the coding process by switching a unit of data which includes the failure for a unit of data which does not include the failure and performing the coding process, and (B) a method for performing the coding process after performing error concealment on the data unit which includes the failure, as the error recovery method.

For example, the data unit is a picture basis, a slice basis or a macroblock basis.

For example, the determination unit determines the error recovery method based on a picture_coding_type included in the bit stream.

For example, the determination unit selects a unit of data which does not include the failure to be switched from a unit of data which includes the failure based on the picture_coding_type of the data unit which includes the failure, and determines the error recovery method in such a way that the data unit which includes the failure is switched to the selected data unit and the coding process is performed on the switched data unit.

For example, the determination unit determines the error recovery method in such a way that the coding process is performed by switching the data unit which includes the failure for the data unit which does not include the failure, only when the picture_coding_type of the data unit which includes the failure is a B picture.

For example, the data unit is a picture basis, a slice basis or a macroblock basis.

For example, the coding method of the bit stream is one of MPEG1, MPEG2, MPEG4 and H.264 formats.

Further, the present invention can be realized as a transcodec method in which the distinguishing constituent units of the transcodec device in the present invention are realized as steps, and as a program of steps to be executed on a computer, and as an integrated circuit which includes the aforementioned distinguishing constituent units.

According to the transcodec device in the present invention, a coding process can be performed when the inputted bit stream includes an error since when the coding process is performed according to the error.

Also, according to the transcodec device in the amount of computations as well as the power consumed in the coding unit can be reduced, since when the frame to be coded is switched, the coding process is performed with the motion vector (MV)=0.

Also, according to the transcodec device in the present invention, even when the inputted bit stream includes errors, a coding process may be performed with high accuracy according to the error, since the error information includes information related to the number of macroblocks (MB) affected by the error. In other words, a coding process which suppresses image quality deterioration can be performed even when the inputted bit stream includes an error.

Also, according to the transcodec device in the present invention, a coding process which suppresses image quality deterioration can be performed even when the inputted bit stream includes an error since the coding process is performed while judging whether or not the error concealment in the decoding unit is appropriate.

Also, according to the transcodec device in the present invention, the coding process is performed after selecting the frame to be switched according to the error information and the picture_coding_type, even when the inputted bit stream includes the error.

Also, according to the transcodec device in the present invention, a coding process which suppresses image quality deterioration can be performed even when the decoding process is interrupted, since the coding process is performed by confirming whether or not the decoding process is interrupted.

### FURTHER INFORMATION ABOUT TECHNICAL BACKGROUND TO THIS APPLICATION

The disclosure of Japanese Patent Application No. 2006-145955 filed on May 25, 2006 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention.

FIG. 1 is a diagram which shows the structure of a conventional transcodec device;

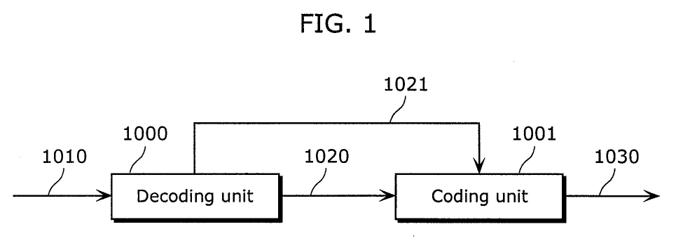

FIG. 2 is a diagram which shows the structure of a transcodec device in the first embodiment;

FIG. 3 is a flowchart which shows a process of the transcodec device in the first embodiment;

FIG. 4 is a diagram which shows the process timing for the transcodec device in the first embodiment;

FIG. 5 is a flowchart which shows a process of the transcodec device in the second embodiment;

FIG. 6 is a diagram which shows the structure of the transcodec device in the third embodiment;

FIG. 7 is a flowchart which shows a process of the transcodec device in the third embodiment;

FIG. 8 is a diagram which shows process timing for the transcodec device in the third embodiment;

FIG. 9 is a diagram which shows the structure of the transcodec device in the fourth embodiment;

FIG. 10 is a diagram which shows a process of the transcodec device in the fourth embodiment;

FIG. 11 is a flowchart which shows a process of the transcodec device in the fourth embodiment;

FIG. 12 is a diagram which shows the structure of the transcodec device in the fifth embodiment;

FIG. 13 is a diagram which shows a process of the transcodec device in the fifth embodiment;

FIG. 14 is a flowchart which shows the process of the transcodec device in the fifth embodiment;

FIG. 15 is a diagram which shows the structure of the transcodec device in the sixth embodiment;

FIG. 16 is a flowchart which shows the process of the transcodec device in the sixth embodiment;

FIG. 17 is a diagram which shows process timing for the transcodec device in the sixth embodiment;

FIG. 18 is a flowchart which shows a process of the transcodec device in the seventh embodiment;

FIG. 19 is a diagram which shows process timing for the transcodec device in the seventh embodiment;

FIG. 20 is a diagram which shows the structure of the transcodec device in the eighth embodiment; and

FIG. 21 is a flowchart which shows a process of the transcodec device in the eighth embodiment.

### DESCRIPTION OF THE PREFERRED EMBODIMENT(S)

Below, an embodiment of the present invention is described in detail with reference to the drawings. Note that the present invention is described using the embodiment and the attached drawings below, however these are presented as examples and the present invention is not limited to these embodiments and drawings. Note that identical units or comparable units in the drawings below have the same numbers attached and the descriptions for these units are not repeated.

The bit stream coding method inputted into the decoding unit is described as “MPEG2 Video” in order to simplify the description of the embodiments.

Note that the bit stream coding method inputted into the decoding unit in the embodiment shown below is MPEG2 Video, however the coding method has no particular specification and may be a coding method such as MPEG1, MPEG4, and H.264. Further, the coding method of the bit stream outputted from the coding unit may be any coding method such as MPEG1, MPEG4, H.264 and MPEG2 Video.

Also, in the embodiments shown below, constituent elements appear, which are called a decoding unit, a coding unit, a control unit and a coding method determination unit. These constituent elements may be equipped as hardware or may be realized by software.

Also, in the embodiments shown below, the decoding unit, the coding unit, the control unit and the coding method determination unit are described as individual constituent elements, however the diagrams which appear in the embodiments are diagrams which express the concept of the invention and do not specify a mounting method for the constituent elements. These constituent elements may be mounted as described below. For example, the control unit and the coding method determination unit may be mounted inside the coding unit.

Also, in the embodiment shown below, the control basis of the coding method determination unit is described as a frame basis however the control basis need not be limited to a frame basis and may, for example, be a picture basis, a slice basis or a macroblock basis.

### First Embodiment

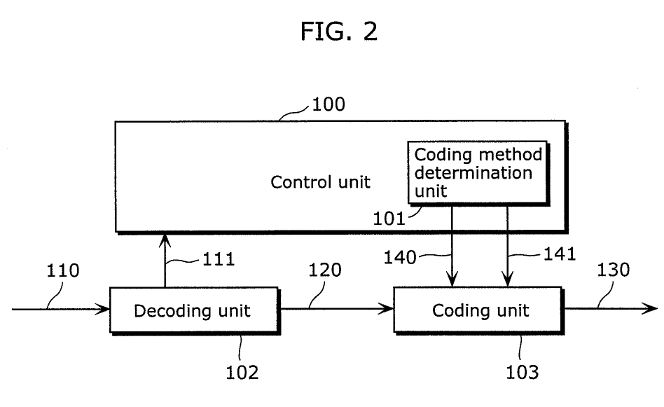

The structure of the transcodec device in the first embodiment is shown in FIG. 2. The transcodec device in the first embodiment is a device which converts an inputted video bit stream which is inputted in a first format into a bit stream in a second format, and includes a decoding unit 102 which decodes the inputted bit stream, a coding unit 103 which codes decoded data outputted from the decoding unit 102, and a control unit 100. The control unit 100 includes a coding method determination unit 101.

The decoding unit 102 loads the inputted bit stream through the signal line 110 and decodes the inputted bit stream. The decoding unit 102 outputs the decoded data through the signal line 120 to the coding unit 103, and further, searches for errors inside the inputted bit stream and outputs information related to the detected errors (below, “error information”) through the signal line 111 to the control unit 100.

The control unit 100 receives error information through the signal line 111. The coding method determination unit 101 in the control unit 100 determines a coding method which includes an error recovery method using the above mentioned error information and notifies the coding unit 103 through the signal line 140 of the coding method determined, and notifies the coding unit 103 through the signal line 141 that the coding process starts up.

In this case, the coding method determination unit 101 determines a coding method and notifies the coding method 103, in such a way that a frame to be coded is switched for a frame in which an error is not included and a coding process is performed on the frame (there are cases where the frame is not switched), or in such a way that an error concealment process is performed on the frame to be coded. Here, the “error concealment process” (below, also abbreviated as “error concealment”) is a process of restoring lost data using only data received correctly on the receiving side when a part of the data (for example, an image) is lost due to a transmission error.

The coding unit 103 loads decoded data through the signal line 120 and in addition, loads information related to the coding method through the signal line 140, performs a coding process by receiving the notification that the coding process starts up through the signal line 141 and outputs coded data through the signal line 130.

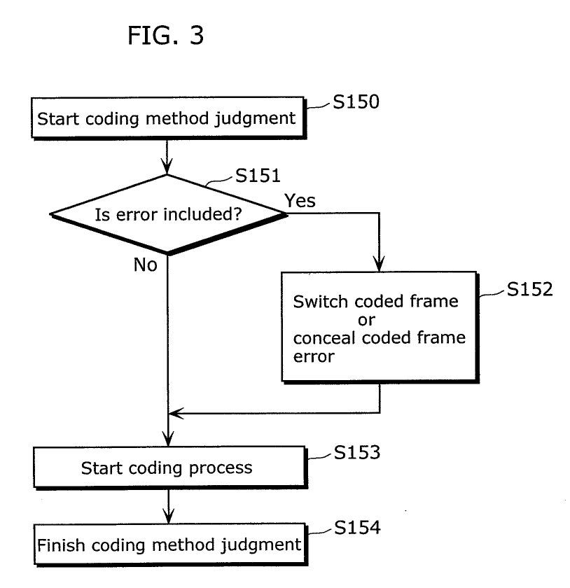

Next, the control flow in the coding method determination unit 101 is shown in FIG. 3. First, the control unit 100 notifies the coding method determination unit 101 that the coding process starts up, on a frame basis. The coding method determination unit 101 receives the start up notification from the control unit 100 and starts a process for determining the coding method in S150. When the coding method determination unit 101 confirms whether or not there is an error included in the frame to be coded, and there is an error (Yes in S151) the process transitions to S152, and transitions to S153 when an error is not included (No in S151). The coding method determination unit 101 determines a coding method (S152) and notifies the coding unit 103, in such a way that the frame to be coded is switched for a frame in which an error is not included and a coding process is performed on the frame (there are cases where the frame is not switched), or in such a way that an error concealment process is performed on the frame to be coded. In S153, the coding method determination unit 101 notifies the coding unit 103 that the coding process starts up, and the process transitions to S154. Next, the coding method determination process finishes on a frame basis in S154.

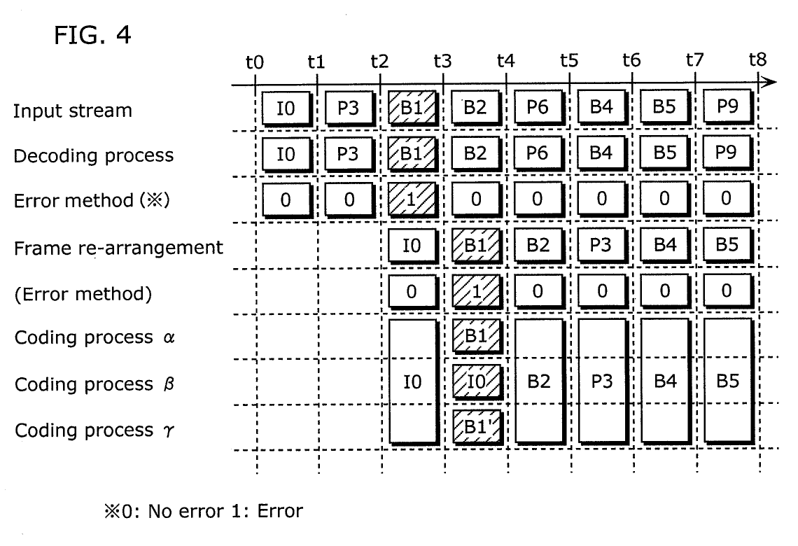

Next, a process flow for the transcodec device is shown in FIG. 4. In FIG. 4, t0, t1, . . . , t8 indicate time, and each interval between times in this case is a frame (for example, 1/30[sec]) interval. Also, I, P and B each indicate an I frame, a P frame and a B frame, and the subscript to I, P and B indicates the display order after performing the decoding process. Here, after the decoding process, the frames are re-arranged in the display order and further, a case is described in which a coding process is performed. Also, the error information is described by “1” when the frame to be coded includes an error and “0” when the frame to be coded does not include an error. Also, the subscript for the coding process (α,β and γ) indicate the coding process pattern.

First, the case where an error is not included in the inputted bit stream is described. At the time t0, the bit stream in the I0 frame is inputted into the decoding unit 102 and the decoding unit 102 performs a frame rearranging process after the decoding process (t0-t1), and outputs the decoded data to the coding unit 103 while searching for errors. Since the I0 frame is a frame which does not include an error, the coding unit 103 codes the I0 frame as-is (time t2-t3).

Next, the process for a case where an error is included in the inputted bit stream is described. At the time t2, the bit stream in the B1 frame is inputted into the decoding unit 102 and the decoding unit 102 performs a frame rearranging process after the decoding process (time t2-t3), and outputs the decoded data to the coding unit 103 while searching for errors. Since the B1 frame is a frame which includes an error, the coding unit 103 performs a coding process according to the coding method notified from the coding method determination unit 101 (time t3-t4).

The coding process α, β and γ are coding process patterns performed by the coding unit 103. In the coding process a pattern, a B1 frame is coded as-is without the frame to be coded being switched, even when the frame to be coded is a frame which includes an error. In the coding process pattern β, when the frame to be coded includes an error, the frame to be coded is coded after being switched with a frame which does not include an error (in the example in FIG. 4, being switched with an I0 frame). In the coding process γ pattern, when the frame to be coded includes an error, the frame is coded after an error concealment process is performed on the frame to be coded (the B1 frame after the error concealment process is performed is B1′).

In the description above, the coding process is performed after the decoding process and after re-arranging the display order of the frames, however the present invention is not limited to re-arranging frames and can be realized without a process for re-arranging frames.

Also, in the description above, the frame which includes an error is described as a B1 frame, however the frame which includes an error is not limited to being a B1 frame.

Also, in the description above, the coding process pattern is described as coding processes α, β and γ, however the pattern is not limited to these three patterns.

In this way, according to the first embodiment, even when an error is included in the inputted bit stream, a coding process that suppresses image quality deterioration can be performed, since the coding process can be performed according to information about the error.

### Second Embodiment

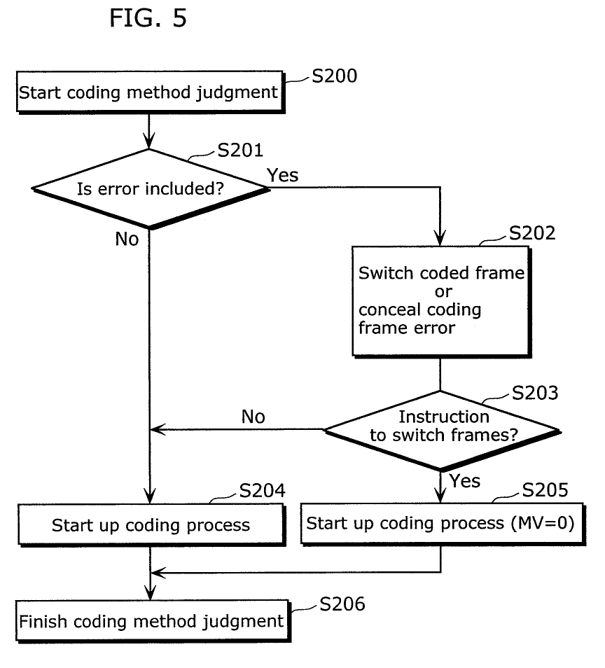

A control flow for the coding method determination unit 101 in the transcodec device in the second embodiment is shown in FIG. 5. Note that the transcodec device in the second embodiment differs from the transcodec device in the first embodiment above only in the control flow of the coding method determination unit 101.

First, the control unit 100 notifies the coding method determination unit 101 that the coding process starts up on a frame basis. The coding method determination unit 101 receives the start up notification from the control unit 100 and starts a process for determining the coding method in S200. The coding method determination unit 101 confirms whether or not an error is included in the frame to be coded in S201. When there is an error (Yes in S201), process of the coding method determination unit 101 transitions to S202 and when there are no errors (No in S201), the process of the transcodec device transitions to S204. The coding method determination unit 101 determines a coding method in S202, notifies the coding unit 103 and the process transitions to S203, determining the coding method in such a way that a frame to be coded is switched for a frame in which an error is not included and a coding process is performed (there are cases where the frame is not switched), or in such a way that an error concealment process is performed on the frame to be coded.

When the coding method determination unit 101 does not issue a direction to switch the coding frame in S202 (No in S203), the process of the transcodec device transitions to S204, and when a direction has been issued to switch frames (Yes in S203), transitions to S205. In S204, the coding method determination unit 101 notifies the coding unit 103 that the coding process starts up, and the process transitions to S206. In addition to notifying the coding unit 103 in S205 in order to perform the coding process with motion vectors (below, abbreviated as MV)=0, the coding method determination unit 101 notifies the coding unit 103 that the coding process starts up and the process transitions to S206. Next, the coding method determination process on a frame basis finishes in S206.

In this way, according to the second embodiment, even when an error is included in the inputted bit stream, a coding process that suppresses image quality deterioration can be performed, since the coding process can be performed according to error information.

Also, when the frame to be coded has been switched, the calculation amount and the power consumption amount can be reduced in the coding unit 103, since the coding process is performed with MV=0.

### Third Embodiment

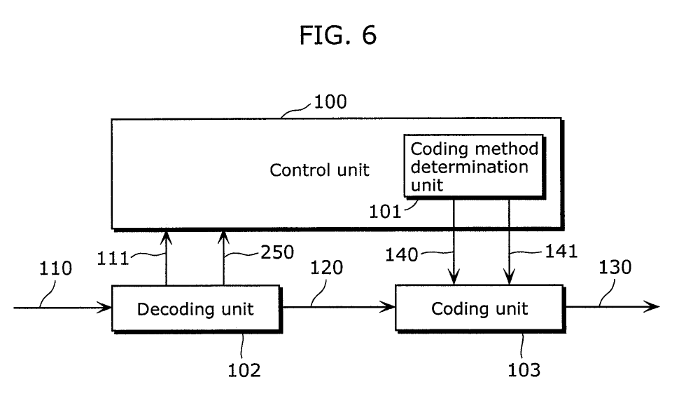

The structure of the transcodec device in the third embodiment is shown in FIG. 6. The transcodec device in the third embodiment includes a decoding unit 102 which decodes an inputted bit stream, a coding unit 103 which codes decoded data outputted from the decoding unit 102, and a control unit 100. The control unit 100 includes a coding method determination unit 101.

The decoding unit 102 loads the inputted bit stream through the signal line 110 and decodes the inputted bit stream. The decoding unit 102 outputs the decoded data through the signal line 120 to the coding unit 103, and further, searches for errors inside the inputted bit stream and outputs information related to the detected errors (error information) through the signal line 111 to the control unit 100. Further, the decoding unit 102 outputs the number of macroblocks (below, abbreviated as “MB”) which have been affected by an error through the signal line 250 to the control unit 100. The control unit 100 receives the error information through the signal line 111 and further receives the number of MBs which have been affected by an error through the signal line 250. The coding method determination unit 101 in the control unit 100 determines a coding method which includes an error recovery method using the error information and the number of MBs affected by an error, notifies the coding unit 103 of the coding method through the signal line 140, and notifies the coding unit 103 through the signal line 141 that the coding process starts up. The coding unit 103 loads decoded data through the signal line 120 and loads information related to the coding method through the signal line 140. Further, the coding unit 103 receives the notification that the coding process starts up through the signal line 141, performs the coding process, and outputs the coded data through the signal line 130.

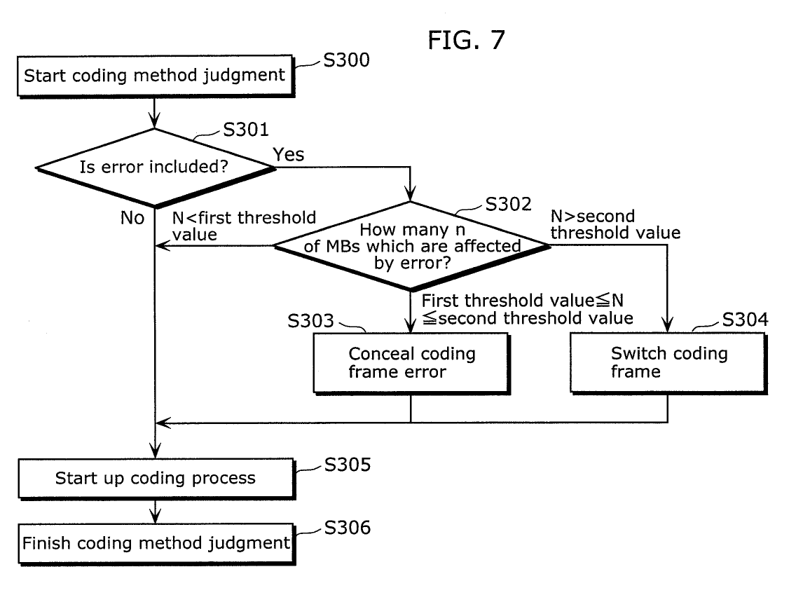

Next, a control flow for the coding method determination unit 101 is shown in FIG. 7. First, the control unit 100 notifies the coding method determination unit 101 that the coding process starts up on a frame basis. The coding method determination unit 101 receives the start up notification from the control unit 100 and starts to determine the coding method in S300. In S301, the coding method determination unit 101 confirms whether or not there is an error included in the frame to be coded; when an error is included (Yes in S301), the process of the coding method determination unit 101 transitions to S302, and when an error is not included, the process of the coding method determination unit 101 transitions to S305 (No in S151).

The coding method determination unit 101 surveys the number of MBs which are affected by an error in the frame to be coded in S302. When the number of MBs which are affected by an error is less than a first threshold value in S302, the process of the coding method determination unit 101 transitions to S305, and when the number of MBs affected by an error is larger than the first threshold value and more than a second threshold value, the process of the coding method determination unit 101 transitions to S304, and in any other case, the process of the coding method determination unit 101 transitions to S303.

The coding method determination unit 101 determines a coding method in such a way that an error concealment process is performed on the frame to be coded, and the process of the coding method determination unit 101 transitions to S305. The coding method determination unit 101 determines a coding method, in such a way that the frame to be coded is switched for a frame in which an error is not included and a coding process is performed on the frame (there are cases where the frame is not switched); the process of the coding method determination unit 101 transitions to S305. In S305, the coding method determination unit 101 notifies the coding unit 103 that the coding process starts up, and the process transitions to S306. Next, the coding method determination process on a frame basis finishes in S306.

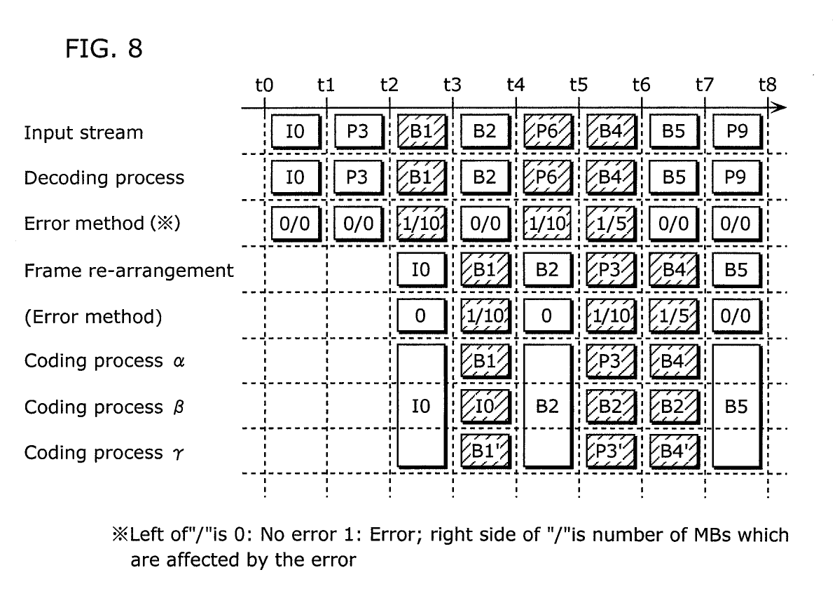

Next, a process flow for the transcodec device is shown in FIG. 8. In FIG. 8, t0, t1, . . . , t8 indicate time, and in this case the interval for each time is a frame (for example, 1/30[sec]) interval. Also, I, P and B each indicate an I frame, a P frame and a B frame respectively in MPEG2 Video, and the subscripts of I, P and B indicate the display order after the decoding process is performed. Here, a case is described in which a coding process is performed after the decoding process, and after the frames are re-arranged into a display order. Also, the left side of “/” in the error information indicates whether or not there is an error (when an error is included, “1”, when an error is not included, “0”) and the right side indicates the number of MBs which are affected by an error.

First, a process for the case where an error is not included in the inputted bit stream is described. At the time t0, the bit stream in the I0 frame is inputted into the decoding unit 102 and the decoding unit 102 performs a frame rearranging process after the decoding process (time t0-t1), outputs the decoded data to the coding unit 103 and searches for errors. Since the I0 frame is a frame which does not include an error, the coding unit 103 codes the I0 frame as-is (time t2-t3).

Next, a case where an error is included in the inputted bit stream is described. At the time t2, the bit stream in the B1 frame is inputted into the decoding unit 102, the decoding unit 102 performing a frame rearranging process after performing the decoding process (t2-t3), and outputting the decoded data to the coding unit 103 as well as searching for errors. Since the B1 frame is a frame which includes an error, the coding unit 103 performs the coding process according to the coding method notified from the coding method determination unit 101.

The coding process α, β and γ are coding process patterns performed by the coding unit 103. The coding process a pattern is a process for the case where it is determined that the number of MBs affected by an error is smaller than the first threshold value, and the B1 frame is coded as-is without the frame to be coded being switched, even when the frame to be coded is a frame which includes an error. In the coding process pattern β, when it is determined that the number of MBs affected by an error is greater than the first threshold value and greater than the second threshold value, the frame to be coded is coded after being switched with a frame which does not include an error (in the example in FIG. 8, being switched to an I0 frame). The coding process γ pattern is a process in which it is determined that the number of MBs which are affected by an error is greater than or equal to the first threshold value and less than or equal to the second threshold value, and in this case, after errors are concealed in the frame to be coded (after the error concealment process is performed, the B1 frame is B1′), the frame is coded (time t3-t4).

In the description above, after the decoding process, the coding process is further performed by re-arranging the frames into the display order, however the present invention is not limited to re-arranging frames and can be realized without a process for re-arranging frames.

Also, in the description above, the frame which includes an error is described as a B1 frame, however the frame which includes an error is not limited to the B1 frame.

Also, in the description above, the coding process pattern is described as coding processes α,β and γ, however the pattern is not limited to these three patterns.

In this way, according to the third embodiment, the coding process can be performed according to the error information with a high degree of accuracy, even when the inputted bit stream includes an error, since the error information includes information related to the number of MBs which are affected by an error. As a result, a coding process that suppresses image deterioration can be performed even when the inputted bit stream includes an error.

### Fourth Embodiment

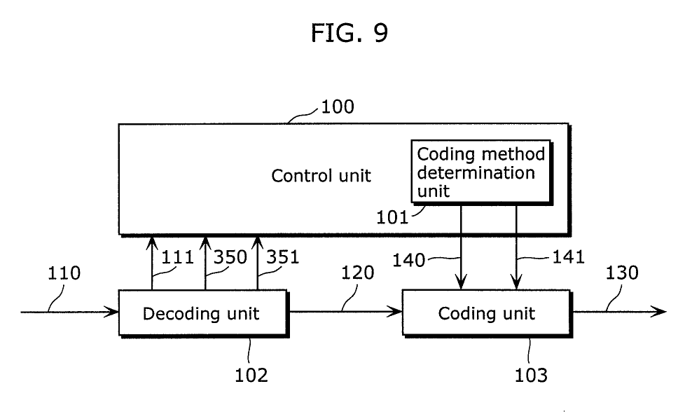

The structure of the transcodec device in the fourth embodiment is shown in FIG. 9. The transcodec device in the fourth embodiment includes a decoding unit 102 which decodes an inputted bit stream, a coding unit 103 which codes decoded data outputted from the decoding unit 102, and a control unit 100. The control unit 100 includes a coding method determination unit 101.

The decoding unit 102 loads the inputted bit stream through the signal line 110 and performs a decoding process on the inputted bit stream. The decoding unit 102 outputs the decoded data through the signal line 120 to the coding unit 103, and further, searches for errors inside the inputted bit stream, outputs information related to the detected errors (error information) through the signal line 111 to the control unit 100, outputs information about decoded motion vectors (MV) through the signal line 350 to the control unit 100 and further outputs the MV information used in error concealment through the signal line 351 to the control unit 100.

The control unit 100 accepts the error information through the signal line 111, accepts the information about the decoded MV through the signal line 350 and further accepts information about the MV used during error concealment through the signal line 351. The coding method determination unit 101 in the control unit 100 determines a coding method which includes an error recovery method that uses the error information, the decoded MV and the number of MBs used in error concealment, notifies the coding unit 103 of the coding method through the signal line 140, and notifies the coding unit 103 through the signal line 141 to start up the coding process.

The coding unit 103 loads decoded data through the signal line 120 and loads information related to the coding method through the signal line 140, performing a coding process by receiving the notification that the coding process starts up through the signal line 141 and outputting coded data through the signal line 130.

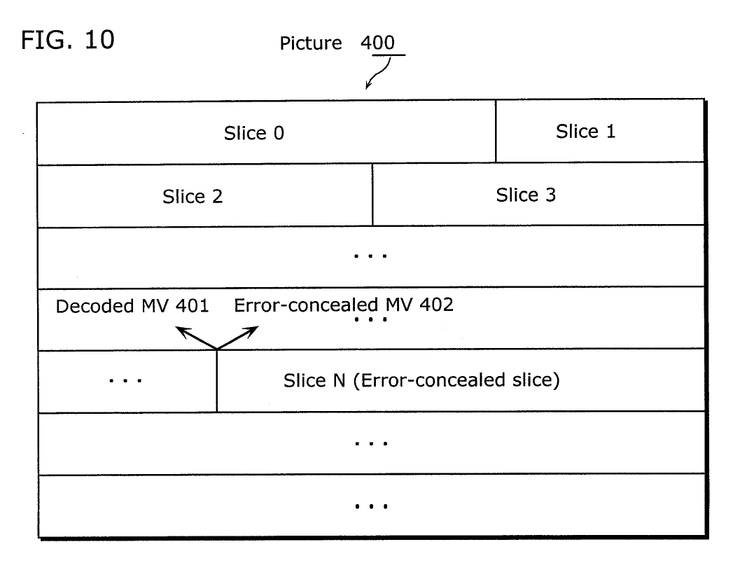

FIG. 10 is a figure which shows an image in which the frames have been decoded, and the picture 400 is composed of plural slice layers (Slice 0, Slice 1, . . . , Slice N, . . . ). FIG. 10 shows the case in which an error occurs in slice N and an error concealment process is performed by the decoding unit 102 on the slice N. The decoding unit 102 notifies the decoded MV information 401 to the control unit 100 on an MB basis, and notifies the MV information 402 used during the error concealment process to the control unit 100. The coding method determination unit 101 determines the coding method using the decoded MV and the MV used during the error concealment process.

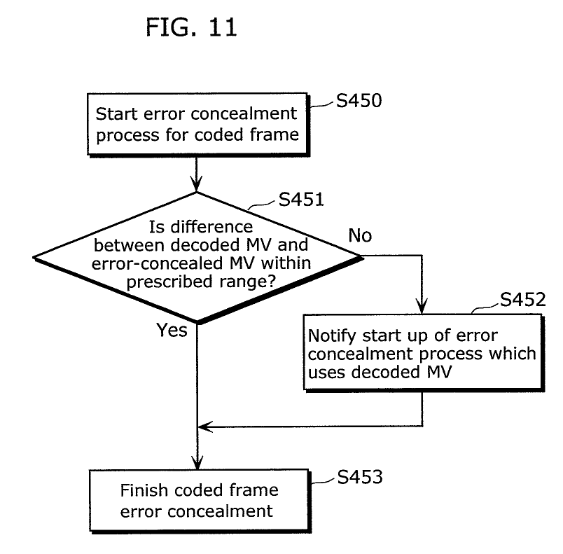

Next, the control flow in the coded frame error concealment process routine for the coding method determination unit 101 is shown in FIG. 11. Below, only the process is shown when the coding method determination unit 101 has selected the coded frame error concealment process.

After confirming the error information or confirming the number of MBs which are affected by an error, the process of the coding method determination unit 101 transitions to Step S450 and the coding method determination unit 101 starts error concealment for the coded frame when the confirmation result matches a condition. The coding method determination unit 101 confirms the difference between the decoded MV and the MV used in error concealment in S451, transitioning to S453 when the difference is within a prescribed range (Yes in S451) and transitioning to S452 when the difference is outside of the prescribed range (No in S451). The coding method determination unit 101 notifies the coding unit 103 to start up the error concealment process using the decoded MV, and when it finishes, the process of the coding method determination unit 101 transitions to S453. Next, in S453, the coded frame error concealment process routine is finished.

In the explanation above, the control unit 100 is notified of MV information decoded by the decoding unit 102 on an MB basis, however the basis for notifying the control unit 100 of the MV information is not necessarily prescribed as an MB basis, and the basis may be a slice or other basis; there are no limitations for the basis on which MV information is notified.

In this way according to the fourth embodiment, even when the inputted bit stream includes an error, the coding process can be performed while judging whether or not the error concealment by the decoding unit 102 is adequate. As a result, a coding process that suppresses image deterioration can be performed even when the inputted bit stream includes an error.

### Fifth Embodiment

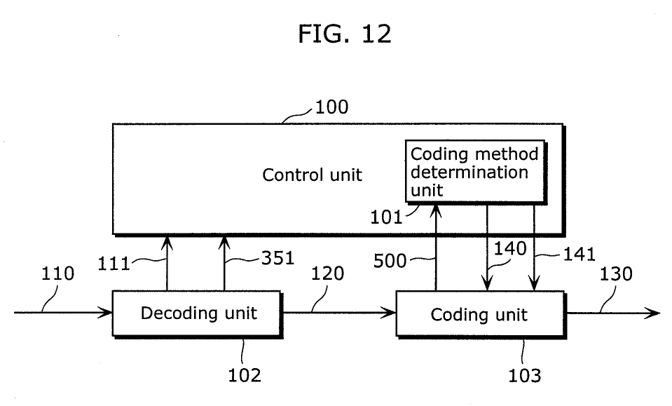

The structure of the transcodec device in the fifth embodiment is shown in FIG. 12. The transcodec device in the fifth embodiment includes a decoding unit 102 which decodes the inputted bit stream, a coding unit 103 which codes decoded data outputted from the decoding unit 102, and a control unit 100. The control unit 100 includes a coding method determination unit 101.

The decoding unit 102 loads the inputted bit stream through the signal line 110 and performs a decoding process on the inputted bit stream. The decoding unit 102 outputs the decoded data through the signal line 120 to the coding unit 103, and further, searches for errors inside the inputted bit stream and outputs information related to the detected errors (error information) through the signal line 111 to the control unit 100. Further, the decoding unit 102 outputs the MV information used during error concealment through the signal line 351 to the control unit 100. The control unit 100 accepts the error information through the signal line 111, accepts the information about the MV used in error concealment through the signal line 351 and further accepts information about the coded MV through the signal line 500.

The coding method determination unit 101 in the control unit 100 determines a coding method which includes an error recovery method that uses the error information, the decoded MV and the MV used in error concealment, notifies the coding unit 103 of the coding method through the signal line 140, and notifies the coding unit 103 that the coding process starts up through the signal line 141. The coding unit 103 loads decoding data through the signal line 120, loads information related to the coding method through the signal line 140, receives the notification that the coding process starts up through the signal line 141 and performs the coding process. Further, the coding unit 103 outputs the coded data through the signal line 130, and outputs information about the coded MV through the signal line 500 to the coding method determination unit 101.

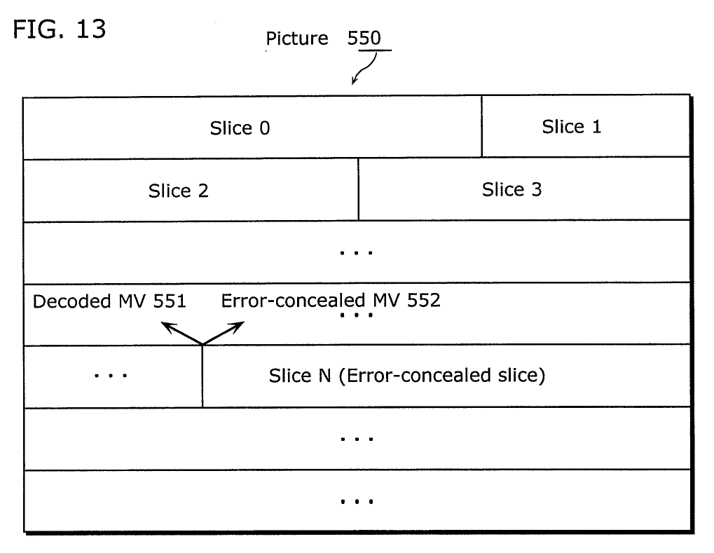

FIG. 13 is a figure which shows an image in which the frames have been decoded, and a picture 550 is composed of plural slice layers (Slice 0, Slice 1, . . . , Slice N, . . . ). FIG. 13 shows a case in which an error occurs in slice N and an error concealment process is performed by the decoding unit 102 on the slice N. The coding unit 102 notifies the control unit 100 of MV552, which is used during the error concealment process, the coding unit 103 notifies the control unit 100 of the coded MV551 on an MB basis, and the coding method determination unit 101 determines the coding method using the coded MV551 and the MV552 used during the error concealment process.

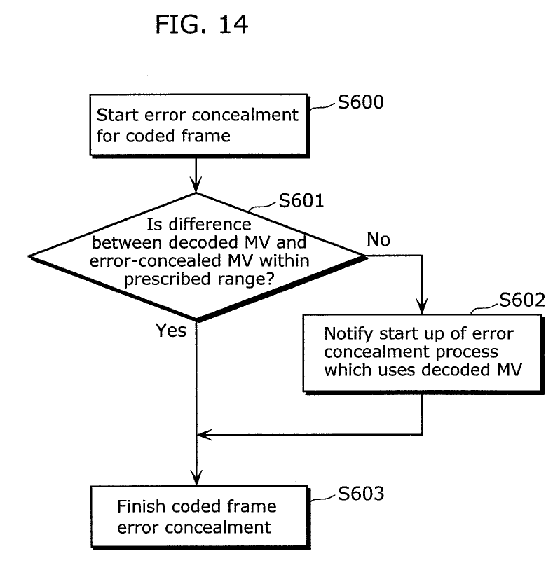

Next, the control flow in the coding frame error concealment process routine in the coding method determination unit 101 is shown in FIG. 14. Below, only the process where the coding method determination unit 101 selects the coding frame error concealment process is shown. When the confirmation result matches the condition, after confirming the error information or confirming the number of MBs which are affected by an error, the process of the coding method determination unit 101 transitions to Step S600 and starts the error concealment process for the coded frame. The coding method determination unit 101 confirms the difference between the coded MV and the MV used during error concealment in S601, and the process transitions to S603 when the difference is within the prescribed range (Yes in S601), and transitions to S602 when the difference is outside of the prescribed range (No in S601). In S602, the coding method determination unit 101 notifies the coding unit 103 that the error concealment process using the decoded MV starts up, and when the error concealment process finishes, the process of the coding method determination unit 101 transitions to S603. Next, in S603, the coding frame error concealment process routine finishes.

In the explanation above, the coding unit 103 notifies the coded MV to the control unit 100 on an MB basis, however the basis on which the coded MV is notified is not limited, is not necessarily prescribed as an MB basis and may be a slice basis or the like.

In this way, according to the fifth embodiment, even when the inputted bit stream includes an error, a coding process which suppresses image quality deterioration can be performed, since the coding process can be performed while judging whether or not the error concealment performed by the decoding unit 102 is adequate.

### Sixth Embodiment

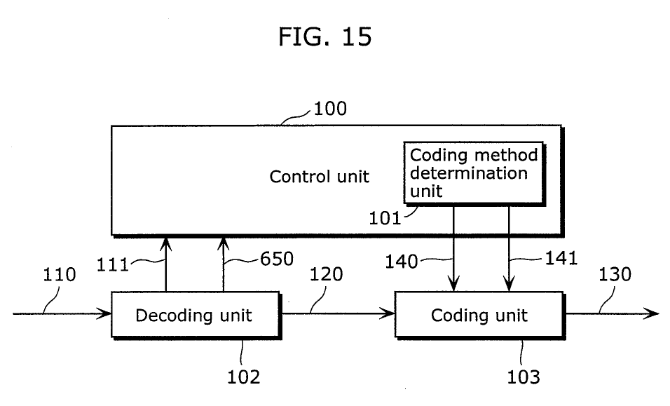

The structure of the transcodec device in the sixth embodiment is shown in FIG. 15. The transcodec device in the sixth embodiment includes the decoding unit 102 which decodes the inputted bit stream, the coding unit 103 which codes decoded data outputted from the decoding unit 102, and the control unit 100. The control unit 100 includes a coding method determination unit 101.

The decoding unit 102 loads the inputted bit stream through the signal line 110 and decodes the inputted bit stream. The decoding unit 102 outputs the decoded data through the signal line 120 to the coding unit 103, and further, searches for errors inside the inputted bit stream, outputting information related to the detected errors (error information) through the signal line 111 to the control unit 100. Further, the decoding unit 102 outputs a decoded picture_coding_type through the signal line 650 to the control unit 100. The control unit 100 receives the error information through the signal line 111 and further receives the picture_coding_type through the signal line 650. The coding method determination unit 101 in the control unit 100 determines a coding method which includes an error recovery method that uses the error information and the picture_coding_type, notifies the coding unit 103 of the coding method through the signal line 140, and notifies the coding unit 103 through the signal line 141 that the coding process starts up. The coding unit 103 loads decoded data through the signal line 120, loads information related to the coding method through the signal line 140, receives the notification that the coding process starts up through the signal line 141, performs a coding process and outputs coding data through the signal line 130.

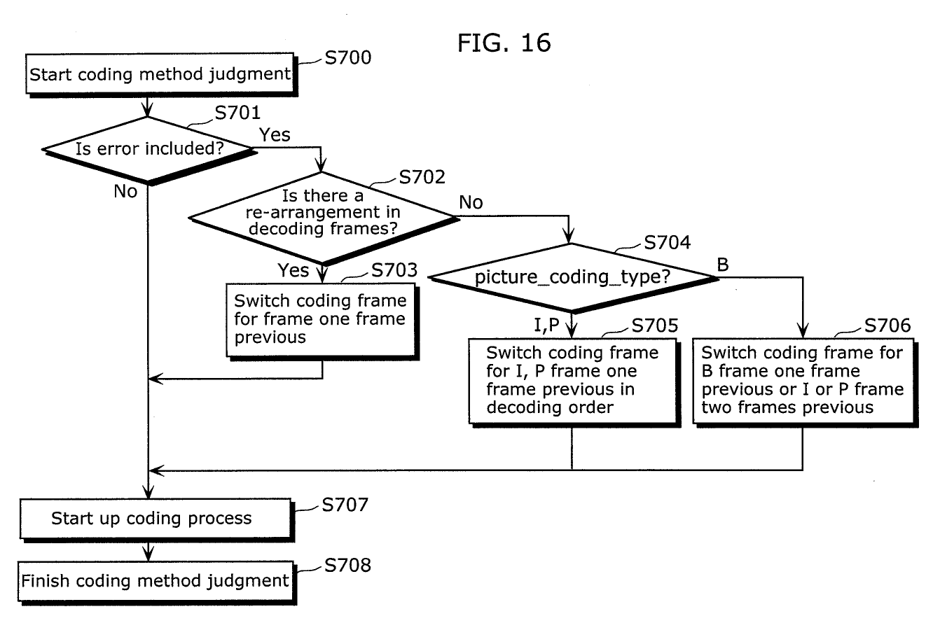

Next, a control flow for the coding method determination unit 101 is shown in FIG. 16. The control unit 100 notifies the coding method determination unit 101 that the coding process starts up on a frame basis. The coding method determination unit 101 receives the start up notification from the control unit 100 and starts to determine the coding method in S700. In S701, the coding method determination unit 101 confirms whether or not there is an error included in the frame to be coded; when an error is included (Yes in S701), the process of the coding method determination unit 101 transitions to S702, and when an error is not included, the process of the transcodec device transitions to S707 (No in S701). In S702, when the decoded frames are re-arranged into the display order (Yes in S702), the process of the coding method determination unit 101 transitions to S703, and when there is not a re-arrangement (No in S702), the process of the coding method determination unit 101 transitions to S704.

In S703, the coding method determination unit 101 determines a coding method in such a way that the coding process is performed after the frame to be coded is switched for a frame one previous (there are cases where the frame is not switched), and the process of the coding method determination unit 101 transitions to S707. In S704, when the picture_coding type is an I frame or a P frame, the process of the coding method determination unit 101 transitions to S705, and when the picture_coding_type is a B frame, the process of the coding method determination unit 101 transitions to S706.

In S705, the coding method determination unit 101 determines a coding method in such a way that the coding process is performed after the frame to be coded is switched for an I frame or a P frame one previous in the decoding order (there are cases where the frame is not switched), and the process of the coding method determination unit 101 transitions to S707. In S706, the coding method determination unit 101 determines a coding method in such a way that the coding process is performed after the frame to be coded is switched for a B frame one previous in the decoding order, an I frame two previous or a P frame (there are cases where the frame is not switched), and the process transitions to S707. In S707, the coding method determination unit 101 notifies the coding unit 103 to start up the coding process, and the process transitions to S708. Next, the coding method determination process on a frame basis finishes in S708.

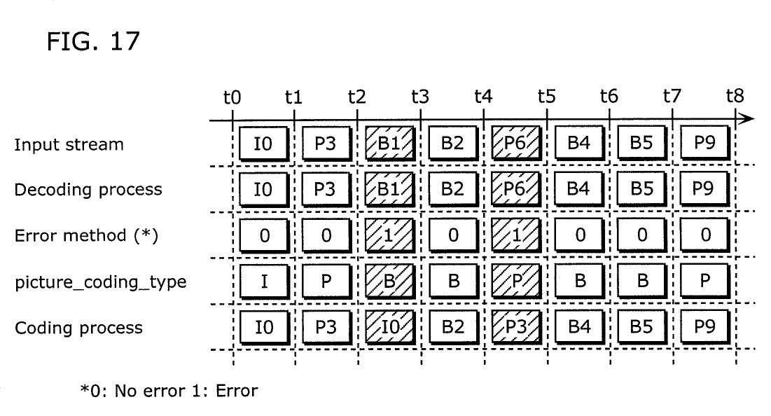

Next, a process flow for the transcodec device is shown in FIG. 17. In FIG. 17, t0, t1, . . . , t8 indicate time, and in this case the interval for each time is a frame (for example, 1/30[sec]) interval. Also, I, P and B respectively indicate an I frame, a P frame and a B frame in the MPEG2 Video, and the I, P and B subscripts indicate the display order after the decoding process. Below, a case is described in which a coding process is performed after the decoding process without re-arranging the frames into the display order. Also, when the frame to be coded includes an error, the error information is indicated by “1”, and when the frame to be coded includes an error, the error information is described by “0”.

First, a process for the case where an error is not included in the inputted bit stream is described. At the time t0, the bit stream in the I0 frame is inputted into the decoding unit 102 and after the decoding process (time t0-t1), the decoding unit 102 outputs the decoded data and searches for errors. Since the I0 frame is a frame which does not include an error, the coding unit 103 codes the I0 frame as-is (time t0-t1).

Next, a case is described in which an error is included in the inputted bit stream and the frame to be coded is a B frame. At the time t2, the bit stream in the B1 frame is inputted into the decoding unit 102 and after the decoding process (time t2-t3), the decoding unit 102 outputs the decoded data and searches for errors. Since the B1 frame is a frame which includes an error, the coding unit 103 performs the coding process according to the coding method notified from the coding method determination unit 101. Here, an example is described in which the frame switching process is performed. Since the frame to be coded includes an error and the frame to be coded is a B frame, the coding unit 103 codes the frame to be coded after switching it with an I0 frame two prior in the decoding order.

Next, a case is described in which an error is included in the inputted bit stream and the frame to be coded is an I frame or a P frame. At the time t4, the bit stream in the P6 frame is inputted into the decoding unit 102 and after decoding (time t4-t5), the decoding unit 102 outputs the decoded data and searches for errors. Since the P6 frame is a frame which includes an error, the coding unit 103 performs the coding process according to the coding method notified from the coding method determination unit 101. Here, an example is described in which the frame switching process is performed. Since the frame to be coded includes an error and the frame to be coded is an I frame or a P frame, the coding unit 103 codes the frame to be coded after switching it with a P3 frame which is a P frame two prior in the decoding order.

In the description above, the coding process is performed after the decoding process without re-arranging the display order of the frames, however the present invention is not limited to not re-arranging the frames and can be realized without a process for re-arranging frames.

Also, in the explanation above, the frame which includes an error is described as a B1 frame and a P6 frame, however the frame which includes an error is not limited to the B1 frame or the P6 frame.

Also, in the explanation above, frame switching is selected as the coding method, however it is not the case that frame switching is the only option.

According to the sixth embodiment, even when an error is included in the inputted bit stream, the coding process can be performed after the frame to be switched is selected according to the error information and the picture_coding_type. As a result, a coding process that suppresses image deterioration can be performed even when the inputted bit stream includes an error.

### Seventh Embodiment

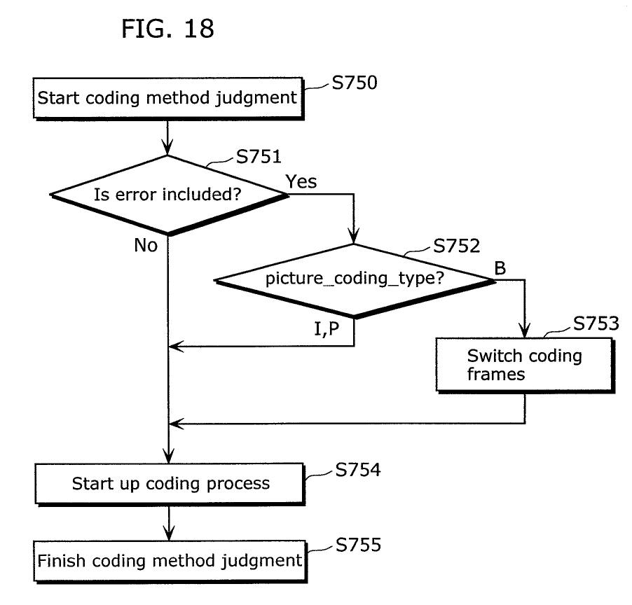

A control flow of the transcodec device in the seventh embodiment is shown in FIG. 18. The transcodec device in the seventh embodiment differs from the transcodec device in the sixth embodiment above only in the control flow of the coding method determination unit 101.

The control unit 100 notifies the coding method determination unit 101 to start up the coding process on a frame basis. The coding method determination unit 101 receives the start up notification from the control unit 100 and starts to determine the coding method in S750. In S751, the coding method determination unit 101 confirms whether or not there is an error included in the frame to be coded and when an error is included (Yes in S751), the process of the transcodec device transitions to S752, and when an error is not included (No in S751), the process of the transcodec device transitions to S754. The process of the coding method determination unit 101 transitions to S754 when the picture_coding_type is an I frame or a P frame in S752, and transitions to S753 when the picture_coding_type is a B picture in S752.

The coding method determination unit 101 determines a coding method which includes an error recovery method such that the frame switching process for the frame to be coded is performed, notifies the coding unit 103 (there are cases where the frame is not switched), and the process transitions to S754. In S754, the coding method determination unit 101 notifies the coding unit 103 that the coding process starts up, and the process transitions to S755. Next, the coding method determination process on a frame basis finishes in S755.

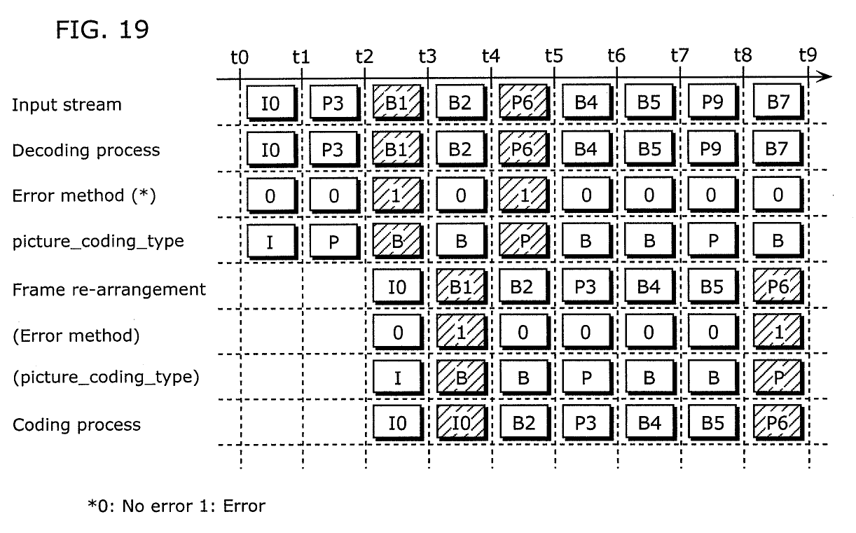

Next, a process flow for the transcodec device is shown in FIG. 19. In FIG. 19, t0, t1, . . . , t8 indicate time, and in this case the interval for each time is a frame (for example, 1/30[sec]) interval. Also, I, P and B each indicate an I frame, a P frame and a B frame in MPEG2 Video, and the subscript to I, P and B indicates the display order after performing the decoding process. Below, a case is described in which a coding process is performed after the decoding process without re-arranging the frames into the display order. Also, the error information is described by “1” when the frame to be coded includes an error and “0” when the frame to be coded does not include an error.

First, a process for the case where an error is not included in the inputted bit stream is described. At the time t0, the bit stream in the I0 frame is inputted into the decoding unit 102 and the decoding unit 102 re-arranges the frames the decoding process (time t0-t1), and outputs the decoded data and searches for errors. Since the 10 frame is a frame which does not include an error, the coding unit 103 codes the I0 frame as-is (time t2-t3).

Next, a process is described for a case in which an error is included in the inputted bit stream and the frame to be coded is a B frame. At the time t2, the bit stream in the B1 frame is inputted into the decoding unit 102 and after the decoding process (time t2-t3), the decoding unit 102 outputs the decoded data and searches for errors. Since the B1 frame is a frame which includes an error, the coding unit 103 performs a coding process according to the coding method which includes an error recovery method, which is notified from the coding method determination unit 101 (time t3-t4). Here, an example is described in which the frame switching process is performed. Since the frame to be coded includes an error and is a B frame, the coding unit 103 codes the frame to be coded after switching it with an 10 frame.

Next, a process is described for a case in which an error is included in the inputted bit stream and the frame to be coded is any frame besides a B frame. At the time t4, the bit stream in the P6 frame is inputted into the decoding unit 102 and after performing the decoding process (time t4-t5), the decoding unit 102 outputs the decoded data and searches for errors. Since the P6 frame is a frame which includes an error, the coding unit 103 performs a coding process according to a coding method which includes an error recovery method, and which is notified from the coding method determination unit 101 (time t8-t9). Here, an example is described in which the frame switching process is performed. Since the frame to be coded includes an error and is any frame besides a B frame, the coding unit 103 codes the frame to be coded without switching it.

In the description above, the coding process is performed after the decoding process and re-arranging the frames into the display order, however the present invention is not limited to having to re-arrange frames and can be realized without the frame re-arranging process.

Also, in the explanation above, the frame which includes the error is described as a B1 frame or a P6 frame, however the frame which includes an error is not limited to the B1 frame or the P6 frame.

Also, in the explanation above, frame switching is selected as the coding method, however it is not the case that frame switching is the only option.

Thus, according to the seventh embodiment, even when an error is included in the inputted bit stream, the coding process frame switching can be selected according to the error information and the picture_coding_type. As a result, a coding process that efficiently suppresses image deterioration can be performed even when the inputted bit stream includes an error.

### Eighth Embodiment

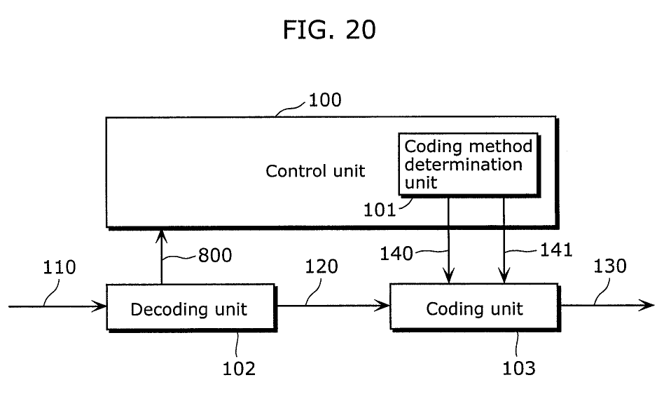

The structure of a transcodec device in the eighth embodiment is shown in FIG. 20. The transcodec device in the eighth embodiment includes the decoding unit 102 which decodes the inputted bit stream, the coding unit 103 which codes decoded data outputted from the decoding unit 102, and the control unit 100. The control unit 100 includes a coding method determination unit 101.

The decoding unit 102 loads the inputted bit stream through the signal line 110 and performs a decoding process on the inputted bit stream. The decoding unit 102 outputs the decoded data through the signal line 120 to the coding unit 103, and further, outputs a decoding interruption notification to the control unit 100 through the signal line 800.

The control unit 100 receives the decoding interruption notification through the signal line 800. The coding method determination unit 101 in the control unit 100 determines a coding method which includes an error recovery method using the decoded interruption notification, notifies the coding unit 103 of the coding method through the signal line 140, and notifies the coding unit 103 to start up the coding process through the signal line 141.

The coding unit 103 loads decoded data through the signal line 120, loads information related to the coding method through the signal line 140, receives the notification that the coding process starts up through the signal line 141, performs the coding process and outputs coded data through the signal line 130.

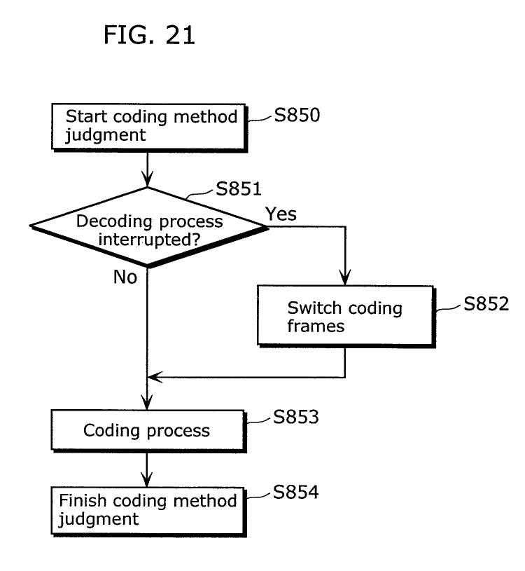

Next, a control flow for the coding method determination unit 101 is shown in FIG. 21. The control unit 100 notifies the coding method determination unit 101 that the coding process starts up on a frame basis.

The coding method determination unit 101 receives the start up notification from the control unit 100 and starts to determine the coding method in S850. In S851, the coding method determination unit 101 confirms whether or not the decoding process has been interrupted in the frame to be coded, and the process transitions to S852 when the decoding process has been interrupted (Yes in S851), and transitions to S853 when the decoding process has not been interrupted (No in S851). The coding method determination unit 101 determines a coding method, in such a way that the frame to be coded is switched for a frame to be coded which does not include an error; a coding process is performed on the frame (there are cases where the frame is not switched), and the process of the coding method determination unit 101 transitions to S853. In S853, the process of the coding method determination unit 101 notifies the coding unit 103 that the coding process starts up, and transitions to S854. Next, the coding method determination process finishes on a frame basis in S854.

Thus, according to the eighth embodiment, it is confirmed whether or not the decoding process has been interrupted, and even when the decoding process has been interrupted, a coding process which suppresses image deterioration can be performed since the decoding process can be performed.

Note that the coding method determination unit 101 in each of the embodiments above is an example of a determination unit for the transcodec device in the present invention.

### INDUSTRIAL APPLICABILITY

The transcodec device in the present invention can be applied to a transcodec device in a storage media such as a digital television, a DVD and a DVR.

What is claimed is:

1. A transcodec device which converts an inputted video bit stream which is in a first format into a video bit stream in a second format, said device comprising:
a decoding unit operable to decode the video bit stream in the first format;
a determination unit operable to determine, when a failure is detected in the video bit stream of the first format during the decoding process by said decoding unit, an error recovery method for a portion of data in which the failure is detected, in such a way that a coding process of the video bit stream is performed by correcting the portion of the data in which the failure is detected using a portion of data in which the failure in the video bit stream in the first format is detected; and
a coding unit operable to code the portion of data in which the failure has been detected, according to the error recovery method determined by said determination unit.

2. The transcodec device according to claim 1,
wherein the failure is a bit stream error which is included in the bit stream, or an failure in which the decoding process is interrupted.

3. The transcodec device according to claim 2,
wherein said determination unit is operable to, determine the error recovery method in such a way that the coding process is performed by switching a unit of data to be coded for a unit of data which does not include the failure, when a unit of data to be coded includes the failure.

4. The transcodec device according to claim 3,
wherein the data unit is a picture basis, a slice basis or a macroblock basis.

5. The transcodec device according to claim 2,
wherein said determination unit is operable to determine the error recovery method in such a way that the coding process is performed by switching a unit of data to be coded for a unit of data which does not include the failure and reduce a motion vector of the switched data unit to 0, when the data unit to be coded includes the failure.

6. The transcodec device according to claim 5,
wherein the data unit is a picture basis, a slice basis or a macroblock basis.

7. The transcodec device according to claim 2,
wherein said determination unit is operable to determine the error recovery method based on the number of macroblocks which are affected by the bit stream error.

8. The transcodec device according to claim 7,
wherein said determination unit is operable to:
(A) determine the error recovery method in such a way that the coding process is performed after error concealment is performed on a frame or a picture which includes the failure when the number of macroblocks which are affected by the bit stream error in the frame or the picture which includes the failure is equal to or greater than a first threshold value and equal to or less than a second threshold value which is greater than the first threshold value; and to
(B) determine the error recovery method in such a way that the coding process is performed by switching the frame or the picture which includes the failure to the frame or picture which does not include the failure when the number of the macroblocks which are affected by the bit stream error in the frame or the picture which includes the failure exceeds the second threshold value.

9. The transcodec device according to claim 2,
wherein said decoding unit is operable to perform error concealment on a unit of data which includes the failure, and
said determination unit is operable to determine the error recovery method based on a difference between a motion vector included in a unit of data which does not include the failure and a motion vector used in error concealment performed by said decoding unit.

10. The transcodec device according to claim 9,
wherein said determination unit is operable to determine the error recovery method in such a way that the coding process is performed after error concealment is performed on the data unit which includes the failure.

11. The transcodec device according to claim 10,
wherein said determination unit is operable to determine the error recovery method in such a way that the coding process is performed after the error concealment process is performed, using the motion vector of the data unit which does not include the failure decoded by said decoding unit, only when the difference is outside of a specified range.

12. The transcodec device according to claim 9,
wherein the data unit is a picture basis, a slice basis or a macroblock basis.

13. The transcodec device according to claim 2,
wherein said decoding unit is operable to perform error concealment on a unit of data which includes the failure; and
said determination unit is operable to determine the error recovery method based on a difference between a motion vector used in error concealment performed by said decoding unit and a motion vector obtained in coding finished by said coding unit.

14. The transcodec device according to claim 13,
wherein said determination unit is operable to determine the error recovery method in such a way that the coding process is performed after error concealment is performed on the data unit which includes the failure.

15. The transcodec device according to claim 14,
wherein said determination unit is operable to determine the error recovery method in such a way that the coding method is performed after error concealment is performed using the motion vector obtained in the coding, only when the difference is outside of a specified range.

16. The transcodec device according to claim 13,
wherein the data unit is a picture basis, a slice basis or a macroblock basis.

17. The transcodec device according to claim 1,
wherein said determination unit is operable to determine one of:
(A) a method for performing the coding process by switching a unit of data which includes the failure for a unit of data which does not include the failure and performing the coding process, and
(B) a method for performing the coding process after performing error concealment on the data unit which includes the failure,
as the error recovery method.

18. The transcodec device according to claim 17,
wherein the data unit is a picture basis, a slice basis or a macroblock basis.

19. The transcodec device according to claim 1,
wherein said determination unit is operable to determine the error recovery method based on a picture_coding_type included in the bit stream.

20. The transcodec device according to claim 19,
wherein said determination unit is operable to select a unit of data which does not include the failure to be switched from a unit of data which includes the failure based on the picture_coding_type of the data unit which includes the failure, and to determine the error recovery method in such a way that the data unit which includes the failure is switched to the selected data unit and the coding process is performed on the switched data unit.

21. The transcodec device according to claim 20,
wherein said determination unit is operable to determine the error recovery method in such a way that the coding process is performed by switching the data unit which includes the failure for the data unit which does not include the failure, only when the picture_coding_type of the data unit which includes the failure is a B picture.

22. The transcodec device according to claim 19,
wherein the data unit is a picture basis, a slice basis or a macroblock basis.

23. The transcodec device according to claim 1,
wherein the coding method of the bit stream is one of MPEG1, MPEG2. MPEG4 and H.264 formats.

24. A transcodec method which converts an inputted video bit stream which is in a first format into a video bit stream in a second format, said method comprising:
decoding the video bit stream in the first format;
determining, when a failure is detected in the video bit stream of the first format during the decoding process by said decoding unit, an error recovery method for a portion of data in which the failure is detected, in such a way that a coding process of the video bit stream is performed by correcting the portion of the data in which the failure is detected using a portion of data in which the failure in the video bit stream in the first format is detected; and
coding the portion of data in which the failure has been detected, according to the error recovery method determined by said determination unit.

25. A program product for executing a transcodec method which converts an inputted video bit stream which is in a first format into a video bit stream in a second format, said program product which, when loaded into a computer, allows the computer to execute said component mounter control method which includes:
decoding the video bit stream in the first format;
determining, when a failure is detected in the video bit stream of the first format during the decoding process by said decoding unit, an error recovery method for a portion of data in which the failure is detected, in such a way that a coding process of the video bit stream is performed by correcting the portion of the data in which the failure is detected using a portion of data in which the failure in the video bit stream in the first format is detected; and
coding the portion of data in which the failure has been detected, according to the error recovery method determined by said determination unit.
